(19) United States
(12) Patent Application Publication
(10) Pub. No.: US 2013/0002350 A1
(43) Pub. Date: Jan. 3, 2013

(54) Differential Comparator

(75) Inventor: Juergen Boldt, Dresden (DE)

(73) Assignee: GLOBALFOUNDRIES INC., Grand Cayman (KY)

(21) Appl. No.: 13/172,117

(22) Filed: Jun. 29, 2011

(51) Int. Cl. H03F 3/45

(52) U.S. Cl. 330/253

(57) ABSTRACT

A comparator includes a differential amplifier having first and second input terminals and first and second output terminals. An input stage is operable to receive first and second input signals. The input stage includes first and second capacitors coupled to the first and second input terminals, respectively. Circuitry is operable to selectively couple the first input signal to the first capacitor and the second input signal to the second capacitor, while coupling the first and second capacitors to the first and second output terminals, respectively, during an offset cancellation phase, and selectively couple the second input signal to the first capacitor and the first input signal to the second capacitor, while isolating the first and second capacitors from first and second output terminals during a comparison phase.

### CROSS-REFERENCE TO RELATED APPLICATIONS

Not applicable.

### STATEMENT REGARDING FEDERALLY SPONSORED RESEARCH OR DEVELOPMENT

Not applicable

### BACKGROUND

The disclosed subject matter relates generally to manufacturing and, more particularly, to electronic circuits having an analog comparator and also relates to integrated circuit devices and designs including an analog comparator circuit.

In electronic designs and circuits, the amplitude of a signal level frequently has to be determined with a specified degree of accuracy. For this purpose, a plurality of techniques have been developed that include the comparison of a first signal level with a second signal level to decide whether the first signal level is higher or lower compared to the second signal level. Thus, a respective electronic circuit may provide a digital response to the question of which of two signals has a higher signal level.

Corresponding electronic circuits may typically be referred to as comparators or analog comparators, when at least one of the two signal levels may vary continuously. Such analog comparator circuits may be used in situations in which a signal is to be compared with a reference signal, which may represent a substantially constant reference or a varying reference, so as to indicate by a digital response when the signal crosses the threshold defined by the reference signal.

A comparator circuit typically comprises an appropriately designed input stage, including a pair of input transistors, which may receive the respective input signals. The comparator may generate a differential voltage that varies depending on the difference of the input signals. The differential voltage may be supplied to an output stage, which is typically designed to provide two predefined output signal levels depending on the voltage across the differential input stage. Consequently, for sophisticated applications, the characteristics of various elements of the comparator may have to be matched to each other to obtain a change of the output signal at a desired minimum value of the difference of the two input signals. Moreover, the response of the comparator circuit to the input signal should typically be as stable as possible for varying operational conditions, such as different temperatures, varying supply voltages, aging of the circuit components, and any other environmental influences, such as humidity, pressure and the like. Typical compensation techniques are complex and may require sophisticated and complex analog circuitry, which may contribute to overall design complexity and production costs.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a comparator. The comparator includes a differential amplifier having first and second input terminals and first and second output terminals. An input stage is operable to receive first and second input signals. The input stage includes first and second capacitors coupled to the first and second input terminals, respectively. Circuitry is operable to selectively couple the first input signal to the first capacitor and the second input signal to the second capacitor, while coupling the first and second capacitors to the first and second output terminals, respectively, during an offset cancellation phase, and selectively couple the second input signal to the first capacitor and the first input signal to the second capacitor, while isolating the first and second capacitors from first and second output terminals during a comparison phase.

Another aspect of the disclosed subject matter is seen in a method for comparing first and second input signals. The first input signal is coupled to a first capacitor and the second input signal is coupled to a second capacitor. The first and second capacitors are coupled to first and second input terminals of a differential amplifier, respectively. The differential amplifier is equalized to store a difference between a voltage of the first input signal and a threshold voltage of the differential amplifier on the first capacitor and store a difference between a voltage of the second input signal and the threshold voltage of the differential amplifier on the second capacitor. The first input signal is coupled to the second capacitor and the second input signal is coupled to the first capacitor after equalizing the differential amplifier. A difference between the first and second input signals is amplified in the differential amplifier. A first logical output is generated responsive to the amplified difference indicating the first input signal has a voltage higher than the second input signal and a second logical output is generated responsive to the amplified difference indicating the first input signal having a voltage lower than the second input signal.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1A is a circuit diagram of a comparator in accordance with one illustrative embodiment of the present subject matter, where the comparator is in a first logic state;

FIG. 1B is a circuit diagram of the comparator of FIG. 1A in a second logic state;

FIG. 2 is a circuit diagram of a pass gate used in the comparator of FIG. 1; and

FIG. 3 is a timing diagram illustrating the operation of the comparator of FIG. 1.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

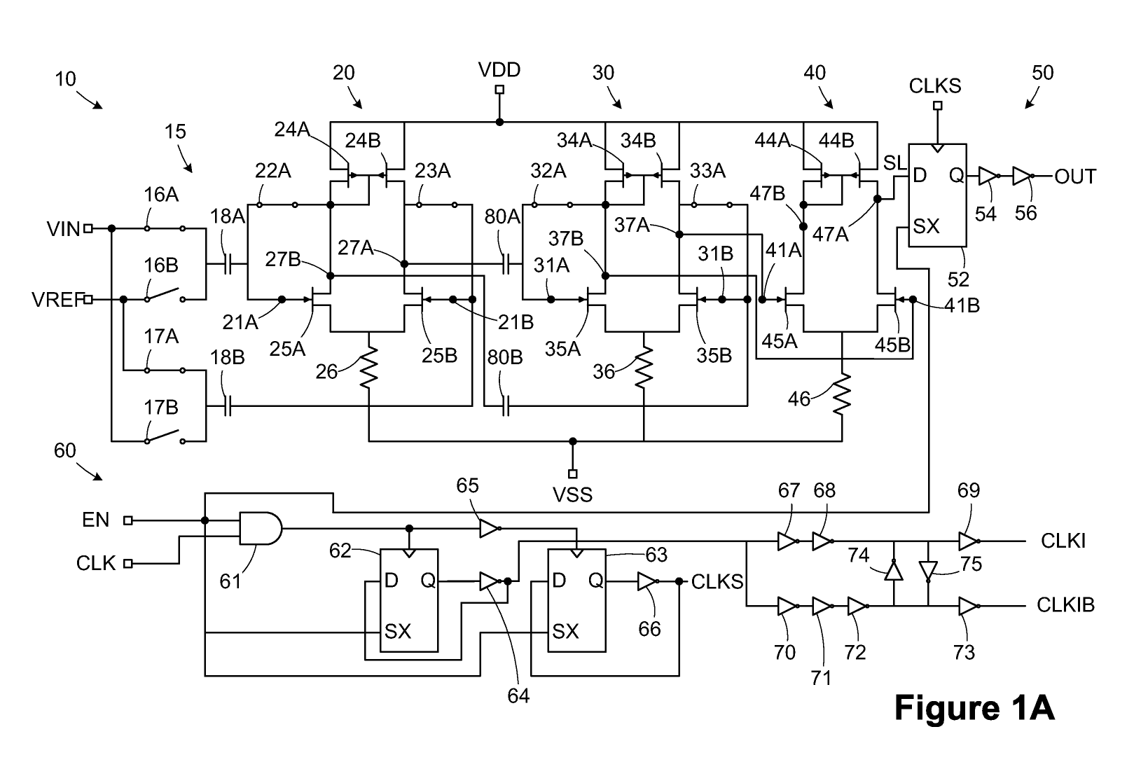

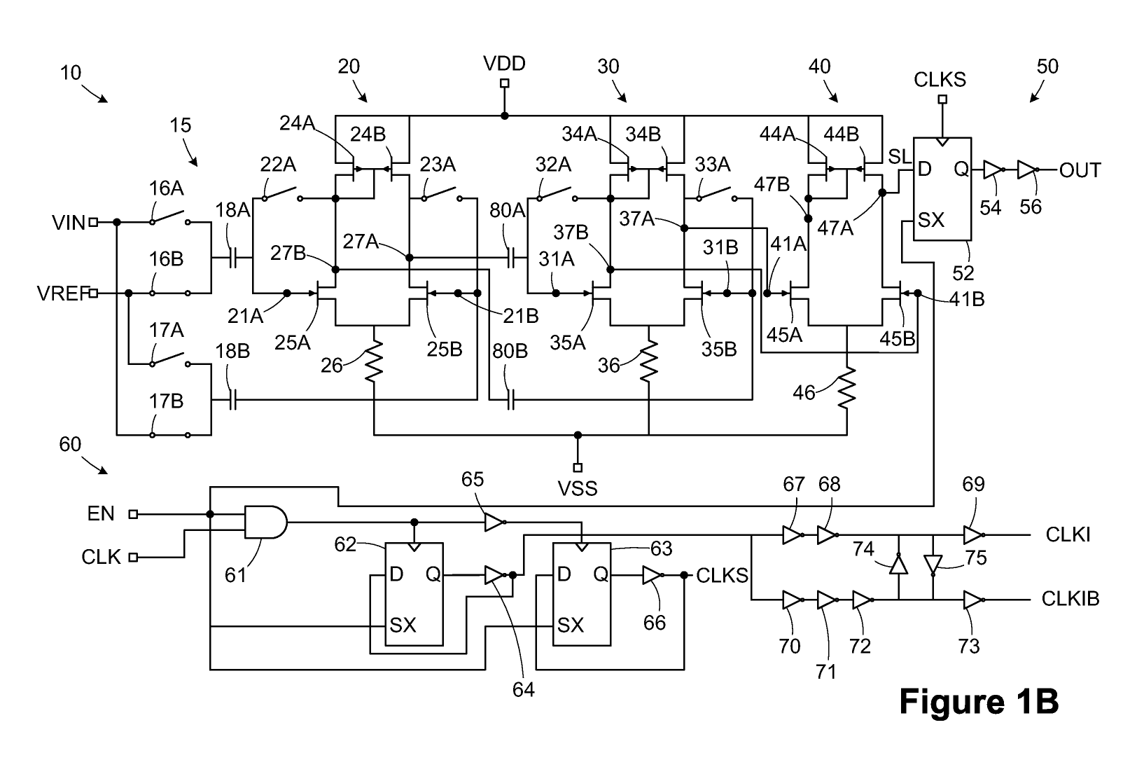

Referring now to the drawings wherein like reference numbers correspond to similar components throughout the several views and, specifically, referring to FIG. 1A, the disclosed subject matter shall be described in the context of a comparator 10. The comparator includes an input stage 15, a first differential amplifier stage 20, a second differential amplifier stage 30, a third differential amplifier stage 40, an output stage 50, and a clock generator 60.

The input stage 15 includes pass gates 16A, 16B coupled to receive an input signal (VIN) and a reference signal (VREF), respectively, and selectively route either the input signal or the reference signal to an input stage capacitor 18A. Pass gates 17A, 17B are coupled selectively route either the input signal or the reference signal to an input stage capacitor 18B.

The first differential amplifier stage 20 includes pass gates 22A, 23A coupled to the capacitors 18A, 18B, respectively, and to input terminals 21A, 21B, respectively. P-type pull-up transistors 24A, 24B are coupled to the pass gates 22A, 23A, respectively, and N-type pull-down transistors 25A, 25B are coupled to the capacitors 18A, 18B, respectively. The sources of the pull-up transistors 24A, 24B are coupled to a high reference voltage, VDD, and the sources of the pull-down transistors 25A, 25B are coupled through a pull-down resistor 26 to a low reference voltage, VSS. The output terminals 27A, 27B of the first differential amplifier stage 20 are provided to intermediate stage capacitors 80A, 80B, respectively.

The intermediate stage capacitors 80A, 80B provide the inputs to the second differential amplifier stage 30. The second differential amplifier stage 30 has essentially the same construction as the first differential amplifier 20. The second differential amplifier stage 30 includes pass gates 32A, 33A coupled to the capacitors 80A, 80B, respectively, and to input terminals 31A, 31B, respectively. P-type pull-up transistors 34A, 34B are coupled to the pass gates 32A, 33A, respectively, and N-type pull-down transistors 35A, 35B are coupled to the capacitors 80A, 80B, respectively. The sources of the pull-up transistors 34A, 34B are coupled to VDD, and the sources of the pull-down transistors 35A, 35B are coupled through a pull-down resistor 36 to VSS. The output terminals 37A, 37B of the second differential amplifier stage 30 are provided to the input terminals 41A, 41B of the third differential amplifier stage 30.

The third differential amplifier stage 40 includes P-type pull-up transistors 44A, 44B and N-type pull-down transistors 45A, 45B. The N-type pull-down transistors 45A, 45B are coupled to the outputs of the second differential amplifier stage 30. The sources of the pull-up transistors 44A, 44B are coupled to VDD, and the sources of the pull-down transistors 45A, 45B are coupled through a pull-down resistor 46 to VSS. An output terminal 47A of the third differential amplifier stage 40 is provided to the output stage 50. The other output terminal 47B of the third differential amplifier stage 40 is left unconnected.

The output stage 50 includes a sampling latch 52 connected to the output terminal 47A. The output of the sampling latch 52 is passed through inverters 54, 56, thereby provided a digital output signal, OUT, indicating whether the input signal is higher than the reference signal (logic “1”) or the input signal is lower than the reference signal (logic “0”).

The clock generator 60 includes an AND gate 61 coupled to receive an enable signal, EN, and external clock signal, CLK. A data flip flop 62 is clocked by the output of the AND gate 61, The clock signal is inverted by an inverter 65, and the inverted clock signal is received as the clock input to a second data flip flop 63. The output of the data flip flop 62 is provided to an inverter 64 and then fed back to the input of the data flip flop 62, thereby causing the output of the data flip flop 62 to toggle on the falling edge of each clock cycle. Thus, the data flip flop 62 acts as a clock divider generating an output clock signal that is half the frequency of the input clock signal (CLK/2).

The output of the second data flip flop 63 is also inverted by an inverter 66 and fed back to its input. Because the clock signal provided to the data flip flop 63 is inverted, it toggles on the rising edge of the CLK signal. Thus, the output of the inverter 66 defines a sample clock signal, CLKS, which represents the input clock signal divided by two (CLK/2) delayed by half a clock cycle.

The output of the inverter 64 is used to generate clock signals, CLKI and CLKIB for controlling the pass gates 16A, 16B, 17A, 17B, 22A, 23A, 32A, 33A. The output of the inverter 64 is provided to a first network of inverters 67, 68, 69 to delay the clock signal and generate the CLKI signal. The output of the inverter 64 is also provided to a second network of inverters 70, 71, 72, 73 to delay the clock signal and generate the CLKIB signal. Cross-coupled inverters 74, 74 are provided to compensate the delay difference between the CLKI-path (2 inverters) and the CLKIB-path (3 inverters). The cross-coupled inverters 74, 75 have a relatively fast switching behavior due to the positive feedback during switching, thereby supporting the switching of the CLKIB-path. This arrangement provides a more symmetrical shape for the edges of CKLKI and the corresponding edges of CLKIB.

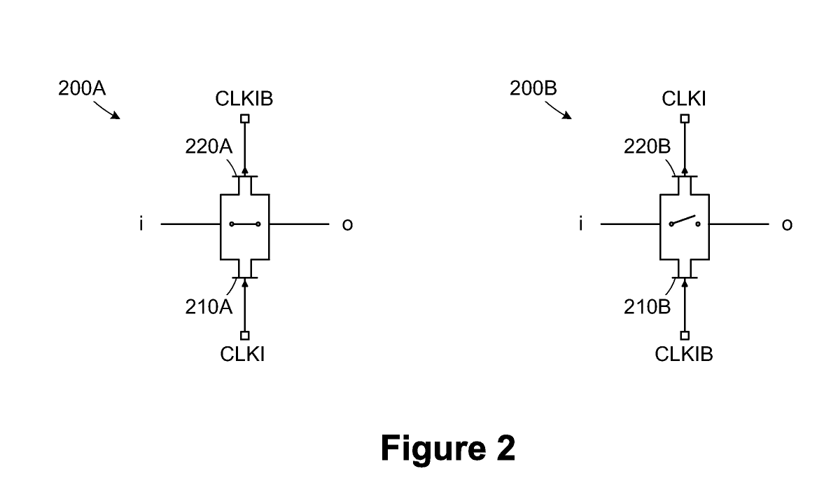

Turning now to FIG. 2, a circuit diagram of exemplary pass gates 200A, 200B is provided. The pass gate 200A includes an N-type transistor 210A controlled by the CLKI signal and a P-type transistor 220A controlled by the CLKIB signal. Hence, the pass gate 200A is closed when the CLKI signal is high and the CLKIB signal is low. The pass gate 200B includes an N-type transistor 210B controlled by the CLKIB signal and a P-type transistor 220B controlled by the CLKI signal. Hence, the pass gate 200B is open when the CLKI signal is high and the CLKIB signal is low. Thus, the pass gates 200A, 200B operate at complimentary logic states. In the comparator 10 illustrated in FIG. 1A, the pass gates 16A, 17A, 22A, 23A, 32A, 33A have the same logic orientation as the pass gate 200A, and the pass gates 16B, 17B have the same logic orientation as the pass gate 200B.

Returning to FIG. 1A, the pass gates 16A, 16B, 17A, 17B, 22A, 23A, 32A, 33A are illustrated as being in a logic state corresponding to CLKI=High and CLKIB=Low, which represents an offset cancellation phase of the comparator 10. The “A” pass gates are closed, and the “B” pass gates are open. In this phase, the pass gates 22A, 23A, 32A, 33A keep the first and second differential amplifier stages 20, 30 at an operating point of VDD/2 by connecting the output terminals 27A, 27B of the differential amplifier stage 20 to the input terminals 21A, 21B. The pass gate 16A routes the input signal, VIN, to the capacitor 18A, and the pass gate 17A routes the reference signal, VREF, to the capacitor 18B. Hence, the input voltage difference (VIN-VREF) and the offset voltage of the first differential amplifier stage are stored on the capacitors 18A, 18B. The capacitor 18A stores the difference between the input voltage and the threshold voltage of the first differential amplifier stage 20, and the capacitor 18B stores the difference between the reference voltage and the threshold voltage of the first differential amplifier stage 20. The output voltage of the first differential amplifier stage 20 and the offset voltage of the second differential amplifier stage 30 are stored on the capacitors 80A, 80B. The second differential amplifier stage 30 operates in the same manner as the first differential amplifier stage 20.

FIG. 1B illustrates the pass gates 16A, 16B, 17A, 17B, 22A, 23A, 32A, 33A as being in a second logic state corresponding to CLKI=Low and CLKIB=High, which represents a comparison phase of the comparator 10. The “A” pass gates are open, and the “B” pass gates are closed. With the pass gates 22A, 23A, 32A, 33A open, the first and second differential amplifier stages 20, 30 operate as amplifiers. The pass gate 16B routes the reference voltage, VREF, to the capacitor 18A, and the pass gate 17B routes the input voltage, VIN, to the capacitor 18B, thereby reversing the polarity. Due to the polarity reversal, The inputs to the first differential amplifier stage 20 become:

(VIN−VREF)−(VREF−VIN)=2(VIN−VREF).

The input voltage difference stored on the capacitors 18A, 18B is amplified by all three differential amplifier voltage stages 20, 30, 40. The sampling latch 52 latches the output voltage of the third differential amplifier stage 40.

In the illustrated embodiment, the third differential amplifier stage 40 is a simple difference amplifier without offset cancellation. Because the first and second differential amplifier stages 20, 30 provide a sufficiently amplified output signal, offset cancellation in the third differential amplifier stage 40 may be omitted. Although differential amplifier stages 20, 30, 40, are illustrated, and only the first and second stages 20, 30 include offset cancellation, it is contemplated that the total number of stages may vary, as well as the number of stages with offset cancellation.

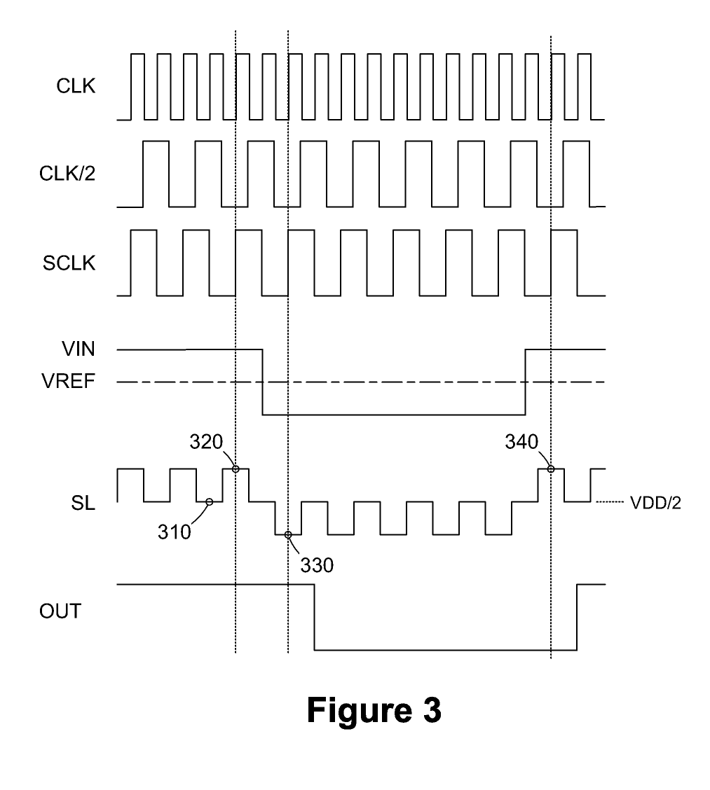

The clock generator 60 defines the relative timings of the CLKI, CLKIB, and CLKS signals to control the phases of the comparator 10. FIG. 3 is a timing diagram 300 illustrating the operation of the comparator 10. The sampling clock, CLKS, represents the input clock signal, CLK, divided by 2 and delayed by a half cycle. The clock signals, CLKI and CLKIB (not shown) are complimentary versions of the input clock signal divided by 2, CLK/2. The effects of the CLKI and CLKIB signals are evident in the signal received at the sampling latch 52, as shown in the SL signal. In the offset cancellation phase illustrated in FIG. 1A, where CLKI=High and CLKIB=LOW, the outputs of the first and second differential amplifier stages 20, 30 are equalized at VDD/2, as represented by point 310. In the comparison phase illustrated in FIG. 1B, where CLKI=LOW and CLKIB=HIGH, the output of the cascaded differential amplifier stages 20, 30, 40 is present at the input to the sampling latch 52, represented by point 320. The sampling latch 52 records the value of the SL signal on rising edges of the SCLK signal.

Note that after the sampling at point 320, the input signal, VIN, transitions from being above the reference voltage, VREF, to being below the reference voltage. The sampling latch 52 detects this change at point 330 during the next comparison phase. At a later time, the input signal transitions high again, and the sampling latch 52 detects this change at point 340.

The comparator 10 described herein exhibits increased measurement accuracy and is sensitive to voltage differences less than 1 mV. Due to the offset compensation, the measurement accuracy is independent of technology variations. The comparator 10 also exhibits good supply/ground noise immunity and robust operation over wide temperate and supply voltage ranges.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A comparator, comprising:
a differential amplifier having first and second input terminals and first and second output terminals;
an input stage operable to receive first and second input signals, the input stage comprising first and second capacitors coupled to the first and second input terminals, respectively; and
circuitry operable to:
selectively couple the first input signal to the first capacitor and the second input signal to the second capacitor, while coupling the first and second capacitors to the first and second output terminals, respectively, during an offset cancellation phase; and
selectively couple the second input signal to the first capacitor and the first input signal to the second capacitor, while isolating the first and second capacitors from first and second output terminals during a comparison phase.

2. The comparator of claim 1, further comprising an output stage coupled to at least one of the first or second output terminals and operable to generate a first logical output responsive to the first input signal having a voltage higher than the second input signal and a second logical output responsive to the first input signal having a voltage lower than the second input signal.

3. The comparator of claim 2, wherein the output stage comprises a latch.

4. The comparator of claim 1, wherein the circuitry comprises:
first and second switches controlled by a first control signal to selectively couple the first input signal to the first capacitor and the second input signal to the second capacitor; and
third and fourth switches controlled by a second control signal to selectively couple the second input signal to the first capacitor and the first input signal to the second capacitor, wherein the second control signal is inverted with respect to the first control signal.

5. The comparator of claim 4, wherein the circuitry further comprises fifth and sixth switches controlled by the first control signal to selectively couple the first output terminal to the first capacitor and the second output terminal to the second capacitor.

6. The comparator of claim 5, further comprising a clock generator operable to generate the first and second control signals.

7. The comparator of claim 1, wherein the differential amplifier comprises a first stage including the first and second input terminals coupled to the first and second capacitors and first and second intermediate output terminals, the comparator further comprises third and fourth capacitors coupled to the first and second intermediate output terminals, respectively, and the differential amplifier further comprises a second stage having first and second intermediate input terminals coupled to the third and fourth capacitors, respectively.

8. The comparator of claim 7, wherein the second stage comprises the first and second output terminals, and the comparator further comprises an output stage coupled to at least one of the first or second output terminals and operable to generate a first logical output responsive to the first input signal having a voltage higher than the second input signal and a second logical output responsive to the first input signal having a voltage lower than the second input signal.

9. The comparator of claim 7, wherein second stage comprises the first and second output terminals, and the circuitry comprises:
first and second switches controlled by a first control signal to selectively couple the first input signal to the first capacitor and the second input signal to the second capacitor, respectively;
third and fourth switches controlled by a second control signal to selectively couple the second input signal to the first capacitor and the first input signal to the second capacitor, respectively, wherein the second control signal is inverted with respect to the first control signal;
fifth and sixth switches controlled by the first control signal to selectively couple the first intermediate output terminal to the first capacitor and the second intermediate output terminal to the second capacitor, respectively; and
seventh and eighth switches controlled by the first control signal to selectively couple the output terminal to the third capacitor and the second output terminal to the fourth capacitor, respectively.

10. The comparator of claim 9, further comprising a clock generator operable to generate the first and second control signals.

11. The comparator of claim 7, wherein the differential amplifier comprises a third stage comprising first and second third stage input terminals coupled to the intermediate output terminals, respectively, and comprising the first and second output terminals, and the comparator further comprises an output stage coupled to at least one of the first or second output terminals and operable to generate a first logical output responsive to the first input signal having a voltage higher than the second input signal and a second logical output responsive to the first input signal having a voltage lower than the second input signal.

12. The comparator of claim 1, wherein the differential amplifier comprises:
first and second pull-down transistors coupled between the first and second output terminals, respectively, and a low reference voltage terminal and having gate inputs coupled to the first and second input terminals; and
first and second pull-up transistors coupled between the first and second output terminals, respectively, and a high reference voltage terminal and having gate inputs coupled to the second output terminal.

13. The comparator of claim 1, wherein the differential amplifier comprises a plurality of stages.

14. A method for comparing first and second input signals, comprising:
coupling the first input signal to a first capacitor and the second input signal to a second capacitor;
coupling the first and second capacitors to first and second input terminals of a differential amplifier, respectively;
equalizing the differential amplifier to store a difference between a voltage of the first input signal and a threshold voltage of the differential amplifier on the first capacitor and store a difference between a voltage of the second input signal and the threshold voltage of the differential amplifier on the second capacitor;
coupling the first input signal to the second capacitor and the second input signal to the first capacitor after equalizing the differential amplifier;
amplifying a difference between the first and second input signals in the differential amplifier; and
generating a first logical output responsive to the amplified difference indicating the first input signal has a voltage higher than the second input signal and a second logical output responsive to the amplified difference indicating the first input signal having a voltage lower than the second input signal.

15. The method of claim 14, wherein equalizing the differential amplifier comprises coupling the first and second input terminals of the differential amplifier to first and second output terminals of the differential amplifier, respectively.

16. The method of claim 14, further comprising isolating the first and second input terminals of the differential amplifier from first and second output terminals of the differential amplifier prior to amplifying the difference.

17. The method of claim 14, further comprising:
controlling first and second switches using a first control signal to selectively couple the first input signal to the first capacitor and the second input signal to the second capacitor; and
controlling third and fourth switches using a second control signal to selectively couple the second input signal to the first capacitor and the first input signal to the second capacitor, wherein the second control signal is inverted with respect to the first control signal.

18. The method of claim 17, wherein equalizing the differential amplifier further comprises controlling fifth and sixth switches using the first control signal to selectively couple a first output terminal of the differential amplifier to the first capacitor and a second output terminal of the differential amplifier to the second capacitor.

19. The method of claim 14, wherein the differential amplifier includes a plurality of stages, including a first stage coupled to the first and second input terminals, and the method further comprises:
coupling first and second intermediate output terminals of the first stage to third and fourth capacitors, respectively;
coupling the third and fourth capacitors to first and second intermediate input terminals of a second stage of the differential amplifier, respectively;
equalizing the first and second stages concurrently to store the difference between the voltage of the first input signal and a threshold voltage of the first stage on the first capacitor, store the difference between a voltage of the second input signal and the threshold voltage of the first stage on the second capacitor, store a difference between the voltage of the first input signal and a threshold voltage of the second stage on the third capacitor, and store a difference between the voltage of the second input signal and the threshold voltage of the second stage on the fourth capacitor; and
amplifying the difference in the first and second stages concurrently.

20. The method of claim 19, wherein the differential amplifier includes a third stage coupled to the second stage, and the method further comprises amplifying the difference in the first, second, and third stages concurrently.
